(19) United States
(12) Patent Application Publication
(10) Pub. No.: US 2022/0180934 A1
(43) Pub. Date: Jun. 9, 2022

(54) READ WINDOW BUDGET OPTIMIZATION FOR THREE DIMENSIONAL CROSSPOINT MEMORY

(71) Applicant: Intel Corporation, Santa Clara, CA (US)

(72) Inventors: Davide Fugazza, San Jose, CA (US); Dany-Sebastien Ly-Gagnon, Santa Clara, CA (US)

(73) Assignee: Intel Corporation, Santa Clara, CA (US)

(21) Appl. No.: 17/114,980

(22) Filed: Dec. 8, 2020

(51) Int. Cl. G11C 16/20; G11C 16/26; G11C 16/30; G11C 16/34

(52) U.S. Cl. CPC G11C 16/20; G11C 16/26; G11C 16/3495; G11C 16/3404; G11C 16/30

(57) ABSTRACT

A memory device including a three dimensional crosspoint memory array comprising memory cells assigned to a plurality of groups, wherein each group is associated with a respective at least one program pulse parameter based on programming responses of memory cells of that group; and access circuitry to program a memory cell of a first group of the plurality of groups to a first program state by applying a program pulse having the at least one program pulse parameter associated with the first group.

### FIELD

The present disclosure relates in general to the field of computer development, and more specifically, to memory devices with cell programmability variations.

### BACKGROUND

A storage device may include non-volatile memory, such as multi-stack 3D crosspoint memory arrays. Memory cells of the memory arrays may be programmed via wordlines and bitlines of the memory array.

### BRIEF DESCRIPTION OF THE DRAWINGS

FIG. 1 illustrates components of a computer system in accordance with certain embodiments.

FIG. 2 illustrates a memory partition in accordance with certain embodiments.

FIG. 3 illustrates a memory cell coupled to access circuitry in accordance with certain embodiments.

FIG. 4 is a perspective view of portions of a three dimensional (3D) crosspoint memory stack in accordance with certain embodiments.

FIG. 5A illustrates an example tile and example threshold voltage (or other voltage) distributions for memory cells at various tile coordinates in accordance with certain embodiments.

FIG. 5B illustrates threshold voltages (or other voltages) of example groups of cells with different cycle counts in accordance with certain embodiments.

FIG. 5C illustrates an example intrinsic read window budget and net read window budget between program states in accordance with certain embodiments.

FIG. 5D illustrates example cell program characteristics in accordance with certain embodiments.

FIGS. 6A-6B illustrate example uncompensated and compensated memory cell threshold voltages (or other voltages) as a function of tile coordinate in accordance with certain embodiments.

FIG. 7 illustrates a crosspoint memory array arranged as a plurality of decks and tiles in accordance with certain embodiments.

FIGS. 8A-8B illustrate example uncompensated and compensated memory cell threshold voltages (or other voltages) as a function of cycle counts in accordance with certain embodiments.

FIG. 9 illustrates a flow for programming a memory cell of a memory array in accordance with certain embodiments.

Like reference numbers and designations in the various drawings indicate like elements.

### DETAILED DESCRIPTION

Although the drawings depict particular computer systems, the concepts of various embodiments are applicable to any suitable computer systems. Examples of systems in which teachings of the present disclosure may be used include desktop computer systems, server computer systems, storage systems, handheld devices, tablets, other thin notebooks, system on a chip (SOC) devices, and embedded applications. Some examples of handheld devices include cellular phones, digital cameras, media players, personal digital assistants (PDAs), and handheld PCs. Embedded applications may include microcontrollers, digital signal processors (DSPs), SOCs, network computers (NetPCs), set-top boxes, network hubs, wide area networks (WANs) switches, or any other system that can perform the functions and operations taught below. Various embodiments of the present disclosure may be used in any suitable computing environment, such as a personal computing device, a server, a mainframe, a cloud computing service provider infrastructure, a datacenter, a communications service provider infrastructure (e.g., one or more portions of an Evolved Packet Core), or other environment comprising one or more computing devices.

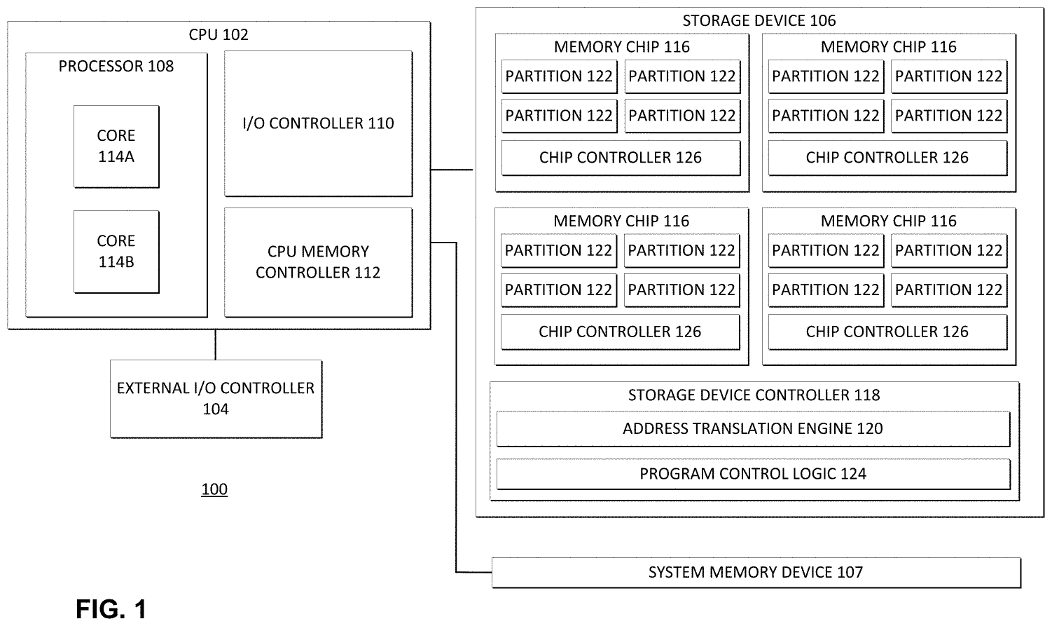

FIG. 1 illustrates components of a computer system 100 in accordance with certain embodiments. System 100 includes a central processing unit (CPU) 102 coupled to an external input/output (I/O) controller 104, a storage device 106 such as a solid state drive (SSD) or a dual inline memory module (DIMM), and system memory device 107. During operation, data may be transferred between a storage device 106 and/or system memory device 107 and the CPU 102. In various embodiments, particular memory access operations (e.g., read and write operations) involving a storage device 106 or system memory device 107 may be issued by an operating system and/or other software applications executed by processor 108. In various embodiments, a storage device 106 may include a storage device controller 118 and one or more memory chips 116 that each comprise any suitable number of memory partitions 122.

In various embodiments, a memory partition 122 may include a 3D crosspoint memory array. In some embodiments, a 3D crosspoint memory array may comprise a transistor-less (e.g., at least with respect to the data storage elements of the memory) stackable crosspoint architecture in which memory cells sit at the intersection of row address lines and column address lines arranged in a grid. In 3D crosspoint memory arrays, a memory cell's programmed state (e.g., ‘0’ or ‘1’ in a single-level cell or ‘00’, ‘10’, ‘01’, or ‘11’ in a multi-level cell) is stored in a cell's threshold voltage (also referred to herein or in the figures as VT or VT) or other voltage of the cell that may be ascertained through any suitable read algorithm (although various portions of the text of this disclosure may refer specifically to threshold voltages, VT, or VT; the teachings associated with such references may also apply to such other voltages in certain embodiments). In some embodiments, the threshold voltage of a programmed memory cell may be function of the pulse width and/or amplitude of a program pulse applied across the terminals of the cell during programming, with a resulting voltage tunability which can span, for example, between 50 mV to 1500 mV, such that any of the desired program states (which may be based on the threshold voltage) can be programmed reliably. In some embodiments, the memory cell's program window is tunable by varying write current (e.g. 1-60 MA/cm²) and/or write pulse-width (e.g., 1-1000 nanoseconds).

In various embodiments, the arrays may be programmed using either unipolar and/or bipolar program pulses. The memory cells may exhibit program windows within given write-read quadrant(s). A write-read quadrant may be defined as a combination of write and read polarities: combinations may be positive-positive, negative-positive, positive-negative, or negative-negative, for write and read polarities, respectively. In unipolar memory operation, read and write polarity are the same, while in bipolar memory operation the write polarity may change for given read polarity (and vice versa).

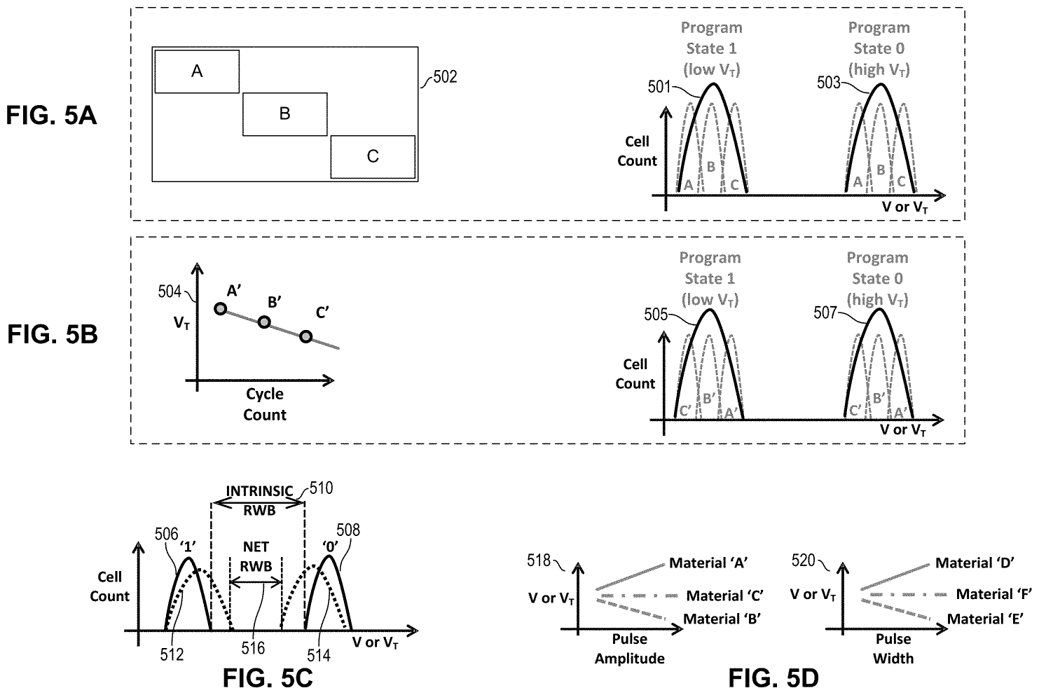

As will be discussed in further detail below (particularly in reference to FIGS. 5A-5D), a read window budget represents the read margin for program state demarcation (e.g., the range of the threshold voltages that is in between the higher end of threshold voltages of cells programmed to a first state and the lower end of threshold voltages cells programmed to a second state). A relatively large read window budget is desirable as it may result in more robust memory read operations. Various characteristics of the memory array may affect the overall size of the read window budget and will be referred to herein as ‘cross-tile’ related, as originated by systematic and/or random component across the memory array or so-called “tiles” (e.g., physical portions of the memory array). For example, cross-tile effects can have a systematic component, such as different path resistances on address lines (e.g., bitlines and wordlines), different parasitic capacitances between address lines may be present in the array, and differences in background leakage, contributing to systematic differences in threshold voltages. Additionally, cross-tile effects can have random components, coming from imperfection in the manufacturing, or differences in cell cycling evolution. As another example, the memory cells of the array may differ in the number of write and/or read cycles performed on the cells. As yet another example, operating temperature may induce a systematic shift of the threshold voltages, due to the nature of the conduction phenomenology in the device comprising the array In some instances, such differences among the cells of the array may widen the distributions of the threshold voltages of the various program states across the memory array, thus shrinking the read window budget.

In various embodiments of the present disclosure, memory cells may be grouped based on one or more characteristics indicative of their programming response, such as their location within the array or their cycle count, and program pulses specific to these groupings may be associated with the groupings. For each grouping, a program pulse may be defined (e.g., via one or more program pulse parameters) for a single program state or multiple program pulses may be defined for multiple program states (with each program pulse corresponding to a single program state). A program pulse for a particular grouping may be defined via the one or more program pulse parameters in terms of one or more of a program pulse amplitude (e.g., a voltage applied to a bitline coupled to the cell, a voltage applied to a wordline coupled to the cell, or a current applied to the memory cell), a program pulse width (e.g., an amount of time the program pulse amplitude is applied to the memory cell), a pulse shape, a combination thereof, or multiple steps of any of the preceding (e.g., a first amplitude may be applied for a first amount of time, then the pulse could be stepped to a second amplitude for a second amount of time, and so on). The pulses may be defined so as to compensate for one of more characteristics of the groups of cells that affect the programming response of the cells in order to normalize the programmed threshold voltages of each group such that the distribution of voltages over the entire memory array for the corresponding program states are narrowed and the size of the read window budget between program states is increased. The increase in size of the read window budget may result in more robust memory operations and/or higher storage density per cell in multi-level cell applications. Specific details regarding such embodiments are described in more detail below.

CPU 102 comprises a processor 108, such as a microprocessor, an embedded processor, a digital signal processor (DSP), a network processor, a handheld processor, an application processor, a co-processor, an SOC, or other device to execute code (e.g., software instructions). Processor 108, in the depicted embodiment, includes two processing elements (cores 114A and 114B in the depicted embodiment), which may include asymmetric processing elements or symmetric processing elements. However, a processor may include any number of processing elements that may be symmetric or asymmetric. CPU 102 may be referred to herein as a host computing device (though a host computing device may be any suitable computing device operable to issue memory access commands to a storage device 106).

In one embodiment, a processing element refers to hardware or logic to support a software thread. Examples of hardware processing elements include: a thread unit, a thread slot, a thread, a process unit, a context, a context unit, a logical processor, a hardware thread, a core, and/or any other element, which is capable of holding a state for a processor, such as an execution state or architectural state. In other words, a processing element, in one embodiment, refers to any hardware capable of being independently associated with code, such as a software thread, operating system, application, or other code. A physical processor (or processor socket) typically refers to an integrated circuit, which potentially includes any number of other processing elements, such as cores or hardware threads.

A core 114 (e.g., 114A or 114B) may refer to logic located on an integrated circuit capable of maintaining an independent architectural state, wherein each independently maintained architectural state is associated with at least some dedicated execution resources. A hardware thread may refer to any logic located on an integrated circuit capable of maintaining an independent architectural state, wherein the independently maintained architectural states share access to execution resources. As can be seen, when certain resources are shared and others are dedicated to an architectural state, the line between the nomenclature of a hardware thread and core overlaps. Yet often, a core and a hardware thread are viewed by an operating system as individual logical processors, where the operating system is able to individually schedule operations on each logical processor.

In various embodiments, the processing elements may also include one or more arithmetic logic units (ALUs), floating point units (FPUs), caches, instruction pipelines, interrupt handling hardware, registers, or other hardware to facilitate the operations of the processing elements.

I/O controller 110 is an integrated I/O controller that includes logic for communicating data between CPU 102 and I/O devices. In other embodiments, the I/O controller 110 may be on a different chip from the CPU 102. I/O devices may refer to any suitable devices capable of transferring data to and/or receiving data from an electronic system, such as CPU 102. For example, an I/O device may comprise an audio/video (A/V) device controller such as a graphics accelerator or audio controller; a data storage device controller, such as a flash memory device, magnetic storage disk, or optical storage disk controller; a wireless transceiver; a network processor; a network interface controller; or a controller for another input device such as a monitor, printer, mouse, keyboard, or scanner; or other suitable device. In a particular embodiment, an I/O device may comprise a storage device 106 coupled to the CPU 102 through I/O controller 110.

An I/O device may communicate with the I/O controller 110 of the CPU 102 using any suitable signaling protocol, such as peripheral component interconnect (PCI), PCI Express (PCIe), Universal Serial Bus (USB), Serial Attached SCSI (SAS), Serial ATA (SATA), Fibre Channel (FC), IEEE 802.3, IEEE 802.11, or other current or future signaling protocol. In particular embodiments, I/O controller 110 and an associated I/O device may communicate data and commands in accordance with a logical device interface specification such as Non-Volatile Memory Express (NVMe) (e.g., as described by one or more of the specifications available at www.nvmexpress.org/specifications/) or Advanced Host Controller Interface (AHCI) (e.g., as described by one or more AHCI specifications such as Serial ATA AHCI: Specification, Rev. 1.3.1 available at http://www.intel.com/content/www/us/en/io/serial-ata/serial-ata-ahci-spec-rev1-3-1.html). In various embodiments, I/O devices coupled to the I/O controller 110 may be located off-chip (e.g., not on the same chip as CPU 102) or may be integrated on the same chip as the CPU 102.

CPU memory controller 112 is an integrated memory controller that controls the flow of data going to and from one or more system memory devices 107. CPU memory controller 112 may include logic operable to read from a system memory device 107, write to a system memory device 107, or to request other operations from a system memory device 107. In various embodiments, CPU memory controller 112 may receive write requests from cores 114 and/or I/O controller 110 and may provide data specified in these requests to a system memory device 107 for storage therein. CPU memory controller 112 may also read data from a system memory device 107 and provide the read data to I/O controller 110 or a core 114. During operation, CPU memory controller 112 may issue commands including one or more addresses of the system memory device 107 in order to read data from or write data to memory (or to perform other operations). In some embodiments, CPU memory controller 112 may be implemented on the same chip as CPU 102, whereas in other embodiments, CPU memory controller 112 may be implemented on a different chip than that of CPU 102. I/O controller 110 may perform similar operations with respect to one or more storage devices 106.

The CPU 102 may also be coupled to one or more other I/O devices through external I/O controller 104. In a particular embodiment, external I/O controller 104 may couple a storage device 106 to the CPU 102. External I/O controller 104 may include logic to manage the flow of data between one or more CPUs 102 and I/O devices. In particular embodiments, external I/O controller 104 is located on a motherboard along with the CPU 102. The external I/O controller 104 may exchange information with components of CPU 102 using point-to-point or other interfaces.

A system memory device 107 may store any suitable data, such as data used by processor 108 to provide the functionality of computer system 100. For example, data associated with programs that are executed or files accessed by cores 114 may be stored in system memory device 107. Thus, a system memory device 107 may include a system memory that stores data and/or sequences of instructions that are executed or otherwise used by the cores 114. In various embodiments, a system memory device 107 may store temporary data, persistent data (e.g., a user's files or instruction sequences) that maintains its state even after power to the system memory device 107 is removed, or a combination thereof. A system memory device 107 may be dedicated to a particular CPU 102 or shared with other devices (e.g., one or more other processors or other devices) of computer system 100.

In various embodiments, a system memory device 107 may include a memory comprising any number of memory partitions, a memory device controller, and other supporting logic (not shown). A memory partition may include non-volatile memory and/or volatile memory.

Non-volatile memory is a storage medium that does not require power to maintain the state of data stored by the medium, thus non-volatile memory may have a determinate state even if power is interrupted to the device housing the memory. Nonlimiting examples of nonvolatile memory may include any or a combination of: 3D crosspoint memory, phase change memory (e.g., memory that uses a chalcogenide glass phase change material in the memory cells), ferroelectric memory, silicon-oxide-nitride-oxide-silicon (SONOS) memory, polymer memory (e.g., ferroelectric polymer memory), ferroelectric transistor random access memory (Fe-TRAM) ovonic memory, anti-ferroelectric memory, nanowire memory, electrically erasable programmable read-only memory (EEPROM), a memristor, single or multi-level phase change memory (PCM), Spin Hall Effect Magnetic RAM (SHE-MRAM), and Spin Transfer Torque Magnetic RAM (STTRAM), a resistive memory, magnetoresistive random access memory (MRAM) memory that incorporates memristor technology, resistive memory including the metal oxide base, the oxygen vacancy base and the conductive bridge Random Access Memory (CB-RAM), a spintronic magnetic junction memory based device, a magnetic tunneling junction (MTJ) based device, a DW (Domain Wall) and SOT (Spin Orbit Transfer) based device, a thiristor based memory device, or a combination of any of the above, or other memory.

Volatile memory is a storage medium that requires power to maintain the state of data stored by the medium (thus volatile memory is memory whose state (and therefore the data stored on it) is indeterminate if power is interrupted to the device housing the memory). Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR3 (double data rate version 3, original release by JEDEC (Joint Electronic Device Engineering Council) on Jun. 27, 2007, currently on release 21), DDR4 (DDR version 4, JESD79-4 initial specification published in September 2012 by JEDEC), DDR4E (DDR version 4, extended, currently in discussion by JEDEC), LPDDR3 (low power DDR version 3, JESD209-3B, August 2013 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5, originally published by JEDEC in January 2020, HBM2 (HBM version 2), originally published by JEDEC in January 2020, or others or combinations of memory technologies, and technologies based on derivatives or extensions of such specifications.

A storage device 106 may store any suitable data, such as data used by processor 108 to provide functionality of computer system 100. For example, data associated with programs that are executed or files accessed by cores 114A and 114B may be stored in storage device 106. Thus, in some embodiments, a storage device 106 may store data and/or sequences of instructions that are executed or otherwise used by the cores 114A and 114B. In various embodiments, a storage device 106 may store persistent data (e.g., a user's files or software application code) that maintains its state even after power to the storage device 106 is removed. A storage device 106 may be dedicated to CPU 102 or shared with other devices (e.g., another CPU or other device) of computer system 100.

In the embodiment depicted, storage device 106 includes a storage device controller 118 and four memory chips 116 each comprising four memory partitions 122 operable to store data, however, a storage device may include any suitable number of memory chips each having any suitable number of memory partitions. A memory partition 122 includes a plurality of memory cells operable to store data. The cells of a memory partition 122 may be arranged in any suitable fashion, such as in rows (e.g., wordlines) and columns (e.g., bitlines), three dimensional structures, sectors, or in other ways. In various embodiments, the cells may be logically grouped into banks, blocks, subblocks, wordlines, pages, frames, bytes, slices, or other suitable groups. In various embodiments, a memory partition 122 may include any of the volatile or non-volatile memories listed above or other suitable memory. In a particular embodiment, each memory partition 122 comprises one or more 3D crosspoint memory arrays. 3D crosspoint arrays are described in more detail in connection with the following figures.

In various embodiments, storage device 106 may comprise a disk drive (e.g., a solid state drive); a memory card; a Universal Serial Bus (USB) drive; a Dual In-line Memory Module (DIMM), such as a Non-Volatile DIMM (NVDIMM); storage integrated within a device such as a smartphone, camera, or media player; or other suitable mass storage device.

In a particular embodiment, one or more memory chips 116 are embodied in a semiconductor package. In various embodiments, a semiconductor package may comprise a casing comprising one or more semiconductor chips (also referred to as dies). A package may also comprise contact pins or leads used to connect to external circuits. In various embodiments, a memory chip may include one or more memory partitions 122.

Accordingly, in some embodiments, storage device 106 may comprise a package that includes a plurality of chips that each include one or more memory partitions 122. However, a storage device 106 may include any suitable arrangement of one or more memory partitions and associated logic in any suitable physical arrangement. For example, memory partitions 122 may be embodied in one or more different physical mediums, such as a circuit board, semiconductor package, semiconductor chip, disk drive, other medium, or any combination thereof.

System memory device 107 and storage device 106 may comprise any suitable types of memory and are not limited to a particular speed, technology, or form factor of memory in various embodiments. For example, a storage device 106 may be a disk drive (such as a solid-state drive), a flash drive, memory integrated with a computing device (e.g., memory integrated on a circuit board of the computing device), a memory module (e.g., a dual in-line memory module) that may be inserted in a memory socket, or other type of storage device. Similarly, system memory 107 may have any suitable form factor. Moreover, computer system 100 may include multiple different types of storage devices.

System memory device 107 or storage device 106 may include any suitable interface to communicate with CPU memory controller 112 or I/O controller 110 using any suitable communication protocol such as a DDR-based protocol, PCI, PCIe, USB, SAS, SATA, FC, System Management Bus (SMBus), or other suitable protocol. In some embodiments, a system memory device 107 or storage device 106 may also include a communication interface to communicate with CPU memory controller 112 or I/O controller 110 in accordance with any suitable logical device interface specification such as NVMe, AHCI, or other suitable specification. In particular embodiments, system memory device 107 or storage device 106 may comprise multiple communication interfaces that each communicate using a separate protocol with CPU memory controller 112 and/or I/O controller 110.

Storage device controller 118 may include logic to receive requests from CPU 102 (e.g., via an interface that communicates with CPU memory controller 112 or I/O controller 110), cause the requests to be carried out with respect to the memory chips 116, and provide data associated with the requests to CPU 102 (e.g., via CPU memory controller 112 or I/O controller 110). Storage device controller 118 may also be operable to detect and/or correct errors encountered during memory operations via an error correction code (ECC engine). In various embodiments, controller 118 may also monitor various characteristics of the storage device 106 such as the temperature or voltage and report associated statistics to the CPU 102. Storage device controller 118 can be implemented on the same circuit board or device as the memory chips 116 or on a different circuit board or device. For example, in some environments, storage device controller 118 may be a centralized storage controller that manages memory operations for multiple different storage devices 106 of computer system 100.

In various embodiments, the storage device 106 also includes program control logic 124 which is operable to control the programming sequence performed when data is written to or read from a memory chip 116. In various embodiments, program control logic 124 may provide the various voltages (or information indicating which voltages should be provided) that are applied to memory cells during the programming and/or reading of data (or perform other operations associated with read or program operations), perform error correction, and perform other suitable functions.

In various embodiments, the program control logic 124 may be integrated on the same chip as the storage device controller 118 or on a different chip. In the depicted embodiment, the program control logic 124 is shown as part of the storage device controller 118, although in various embodiments, all or a portion of the program control logic 124 may be separate from the storage device controller 118 and communicably coupled to the storage device controller 118. For example, all or a portion of the program control logic 124 described herein may be located on a memory chip 116. In various embodiments, reference herein to a “controller” may refer to any suitable control logic, such as storage device controller 118, chip controller 126, or a partition controller. In some embodiments, reference to a controller may contemplate logic distributed on multiple components, such as logic of a storage device controller 118, chip controller 126, and/or a partition controller.

In various embodiments, storage device controller 118 may receive a command from a host device (e.g., CPU 102), determine a target memory chip for the command, and communicate the command to a chip controller 126 of the target memory chip. In some embodiments, the storage device controller 118 may modify the command before sending the command to the chip controller 126.

The chip controller 126 may receive a command from the storage device controller 118 and determine a target memory partition 122 for the command. The chip controller 126 may then send the command to a controller of the determined memory partition 122. In various embodiments, the chip controller 126 may modify the command before sending the command to the controller of the partition 122.

In some embodiments, all or some of the elements of system 100 are resident on (or coupled to) the same circuit board (e.g., a motherboard). In various embodiments, any suitable partitioning between the elements may exist. For example, the elements depicted in CPU 102 may be located on a single die (e.g., on-chip) or package or any of the elements of CPU 102 may be located off-chip or off-package. Similarly, the elements depicted in storage device 106 may be located on a single chip or on multiple chips. In various embodiments, a storage device 106 and a computing host (e.g., CPU 102) may be located on the same circuit board or on the same device and in other embodiments the storage device 106 and the computing host may be located on different circuit boards or devices.

The components of system 100 may be coupled together in any suitable manner. For example, a bus may couple any of the components together. A bus may include any known interconnect, such as a multi-drop bus, a mesh interconnect, a ring interconnect, a point-to-point interconnect, a serial interconnect, a parallel bus, a coherent (e.g. cache coherent) bus, a layered protocol architecture, a differential bus, and a Gunning transceiver logic (GTL) bus. In various embodiments, an integrated I/O subsystem includes point-to-point multiplexing logic between various components of system 100, such as cores 114, one or more CPU memory controllers 112, I/O controller 110, integrated I/O devices, direct memory access (DMA) logic (not shown), etc. In various embodiments, components of computer system 100 may be coupled together through one or more networks comprising any number of intervening network nodes, such as routers, switches, or other computing devices. For example, a computing host (e.g., CPU 102) and the storage device 106 may be communicably coupled through a network.

Although not depicted, system 100 may use a battery and/or power supply outlet connector and associated system to receive power, a display to output data provided by CPU 102, or a network interface allowing the CPU 102 to communicate over a network. In various embodiments, the battery, power supply outlet connector, display, and/or network interface may be communicatively coupled to CPU 102. Other sources of power can be used such as renewable energy (e.g., solar power or motion based power).

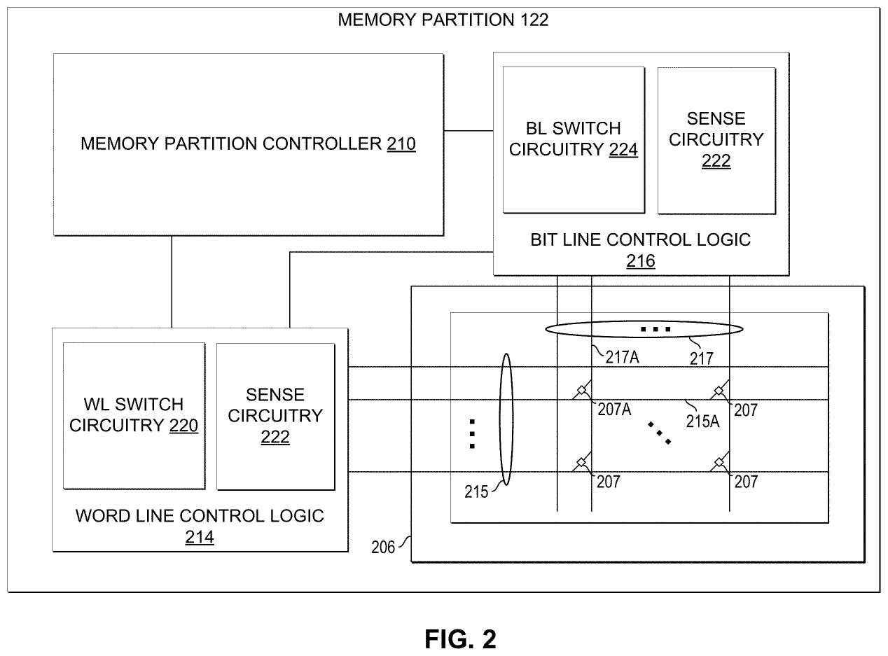

FIG. 2 illustrates a detailed exemplary view of the memory partition 122 of FIG. 1 in accordance with certain embodiments. In one embodiment, a memory partition 122 may include 3D crosspoint memory which may include phase change memory or other suitable memory types. In some embodiments, a 3D crosspoint memory array 206 may comprise a transistor-less (e.g., at least with respect to the data storage elements of the memory) stackable crosspoint architecture in which memory cells 207 sit at the intersection of row address lines and column address lines arranged in a grid. The row address lines 215 and column address lines 217, called wordlines (WLs) and bitlines (BLs), respectively, cross in the formation of the grid and each memory cell 207 is coupled between a WL and a BL where the WL and BL cross (e.g., at a crosspoint). At the point of a crossing, the WL and BL may be located at different vertical planes such that the WL crosses over the BL but does not physically touch the BL. As described above, the architecture may be stackable, such that a wordline may cross over a bitline located beneath the wordline and another bitline for another memory cell located above the wordline. It should be noted that row and column are terms of convenience used to provide a qualitative description of the arrangement of WLs and BLs in crosspoint memory. In various embodiments, the cells of the 3D crosspoint memory array may be individually addressable. In some embodiments, bit storage may be based on a change in bulk resistance of a 3D crosspoint memory cell.

FIG. 2 illustrates a memory partition in accordance with certain embodiments. In the embodiment of FIG. 2, a memory partition 122 includes memory partition controller 210, wordline control logic 214, bitline control logic 216, and memory array 206. A host device (e.g., CPU 102) may provide read and/or write commands including memory address(es) and/or associated data to memory partition 122 (e.g., via storage device controller 118 and chip controller 126) and may receive read data from memory partition 122 (e.g., via the chip controller 126 and storage device controller 118). Similarly, storage device controller 118 may provide host-initiated read and write commands or device-initiated read and write commands including memory addresses to memory partition 122 (e.g., via chip controller 126). Memory partition controller 210 (in conjunction with wordline control logic 214 and bitline control logic 216) is configured to perform memory access operations, e.g., reading one or more target memory cells and/or writing to one or more target memory cells.

Memory array 206 corresponds to at least a portion of a 3D crosspoint memory (e.g., that may include phase change memory cells or other suitable memory cells) and includes a plurality of wordlines 215, a plurality of bitlines 217 and a plurality of memory cells, e.g., memory cells 207. Each memory cell is coupled between a wordline (“WL”) and a bitline (“BL”) at a crosspoint of the WL and the BL.

Memory partition controller 210 may manage communications with chip controller 126 and/or storage device controller 118. In a particular embodiment, memory partition controller 210 may analyze one or more signals received from another controller to determine whether a command sent via a bus is to be consumed by the memory partition 122. For example, controller 210 may analyze an address of the command and/or a value on an enable signal line to determine whether the command applies to the memory partition 122. Controller 210 may be configured to identify one or more target WLs and/or BLs associated with a received memory address (this memory address may be a separate address from the memory partition address that identifies the memory partition 122, although in some embodiments a portion of an address field of a command may identify the memory partition while another portion of the address field may identify one or more WLs and/or BLs). Memory partition controller 210 may be configured to manage operations of WL control logic 214 and BL control logic 216 based, at least in part, on WL and/or BL identifiers included in a received command. Memory partition controller 210 may include memory partition controller circuitry 211, and a memory controller interface 213. Memory controller interface 213, although shown as a single block in FIG. 2, may include a plurality of interfaces, for example a separate interface for each of the WL control logic 214 and the BL control logic 216.

WL control logic 214 includes WL switch circuitry 220 and sense circuitry 222. WL control logic 214 is configured to receive target WL address(es) from memory partition controller 210 and to select one or more WLs for reading and/or writing operations. For example, WL control logic 214 may be configured to select a target WL by coupling a WL select bias voltage to the target WL. WL control logic 214 may be configured to deselect a WL by decoupling the target WL from the WL select bias voltage and/or by coupling a WL deselect bias voltage (e.g., a neutral bias voltage) to the WL. WL control logic 214 may be coupled to a plurality of WLs 215 included in memory array 206. Each WL may be coupled to a number of memory cells corresponding to a number of BLs 217. WL switch circuitry 220 may include a plurality of switches, each switch configured to couple (or decouple) a respective WL, e.g., WL 215A, to a WL select bias voltage to select the respective WL 215A.

BL control logic 216 includes BL switch circuitry 224. In some embodiments, BL control logic 216 may also include sense circuitry, e.g., sense circuitry 222. BL control logic 216 is configured to select one or more BLs for reading and/or writing operations. BL control logic 216 may be configured to select a target BL by coupling a BL select bias voltage to the target BL. BL control logic 216 may be configured to deselect a BL by decoupling the target BL from the BL select bias voltage and/or by coupling a BL deselect bias voltage (e.g., a neutral bias voltage) to the BL. BL switch circuitry 224 is similar to WL switch circuitry 220 except BL switch circuitry 224 is configured to couple the BL select bias voltage to a target BL.

Sense circuitry 222 is configured to detect the state of one or more sensed memory cells 207 (e.g., via the presence or absence of a snap back event during a sense interval), e.g., during a read operation. Sense circuitry 222 is configured to provide a logic level output related to the result of the read operation to, e.g., memory partition controller 210.

As an example, in response to a signal from memory partition controller 210, WL control logic 214 and BL control logic 216 may be configured to select a target memory cell, e.g., memory cell 207A, for a read operation by coupling WL 215A to WL select bias voltage and BL 217A to BL select bias voltage as well as coupling the other WLs and BLs to respective deselect bias voltages. One or both of sense circuitries 222 may then be configured to monitor WL 215A and/or BL 217A for a sensing interval in order to determine the state of the memory cell 207A.

Thus, WL control logic 214 and/or BL control logic 216 may be configured to select a target memory cell for a read operation, initiate the read operation, sense the selected memory cell (e.g., for a snap back event) in a sensing interval, and provide the result of the sensing to, e.g., memory partition controller 210.

In a particular embodiment, the sense circuitry 222 may include a WL load connected to a WL electrode or gate, and a BL load connected to a BL electrode or gate. When a particular wordline and bitline are selected in the array, a difference between WL load or WL voltage and the BL voltage corresponds to a read VDM. VDM may induce a current (icell) in the memory cell 207A dependent on a program state of the memory cell. A comparator such as a sense amplifier may compare icell with a reference current in order to read a logic state of the memory cell. In this manner, an output of the sense amplifier/comparator may be indicative of a state of the target memory cell. A latch may be coupled to the output of the comparator to store the output of the read operation.

For each matrix of arrays, there may be a number of sense amplifiers provided, with the sense circuitry 222 able to process up to a maximum number of sensed bits, such as 128 bits, from the sense amplifiers at one time. Hence, in one embodiment, 128 memory cells may be sensed at one time by sense amplifiers of the sense circuitry 222.

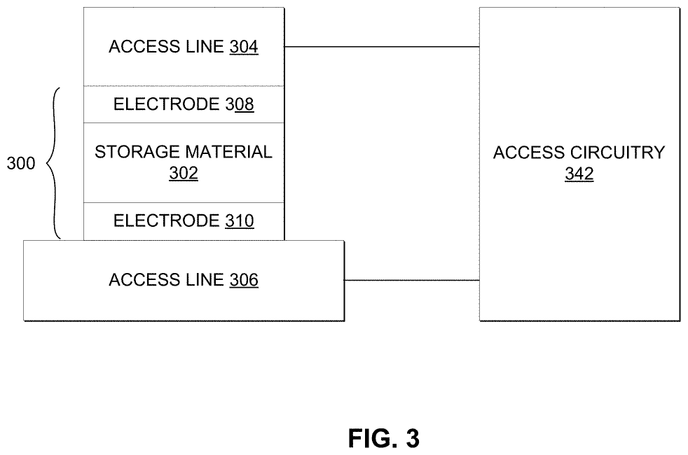

FIG. 3 illustrates a memory cell 300 coupled to access circuitry 342 in accordance with certain embodiments. The memory cell 300 includes a storage material 302 between access lines 304 and 306. The access lines 304, 306 electrically couple the memory cell 300 with access circuitry 342 that writes to and reads the memory cell 300. For example, access circuitry 342 may include WL switch circuitry 220, BL switch circuitry 224, sense circuitry 222, or other suitable circuitry.

In one embodiment, storage material 302 includes a self-selecting material that exhibits memory effects. A self-selecting material is a material that enables selection of a memory cell in an array without requiring a separate selector element. Thus, storage material 302 may represent a “selector/storage material.” A material exhibits memory effects if circuitry (e.g., 342) for accessing memory cells can cause the material to be in one of multiple states (e.g., via a write operation) and later determine the programmed state (e.g., via a read operation). Access circuitry 342 can store information in the memory cell 300 by causing the storage material 302 to be in a particular state. The storage material 302 can include, for example, a chalcogenide material or other material capable of functioning as both a storage element and a selector, to enable addressing a specific memory cell and determining what the state of the memory cell is. Thus, in one embodiment, the memory cell 300 is a self-selecting memory cell that includes a single layer of material that acts as both a selector element to select the memory cell and a memory element to store a logic state. In the embodiment depicted, each memory cell 300 is a two-terminal device (i.e., the memory cell 300 has two electrodes to receive control signals sufficient to write to and read from the memory cell 300).

In other embodiments, each memory cell (e.g., 300) includes a memory element configured to store information and a separate memory cell select device (e.g., selector) coupled to the memory element. Select devices may include ovonic threshold switches, diodes, bipolar junction transistors, field-effect transistors, etc. In one embodiment, a first chalcogenide layer may comprise the memory element and a second chalcogenide layer may comprise the select device.

The storage material 302 may include any suitable material programmable to a plurality of states. In some embodiments, the storage material 302 may include a chalcogenide material comprising a chemical compound with at least one chalcogen ion, that is, an element from group 16 of the periodic table. For example, the storage material 302 may include one or more of: sulfur (S), selenium (Se), or tellurium (Te). Additionally or alternatively, in various embodiments, storage material 302 may comprise germanium (Ge), antimony (Sb), bismuth (Bi), lead (Pb), tin (Sn), indium (In), silver (Ag), arsenic (As), phosphorus (P), molybdenum (Mo), gallium (Ga), aluminum (Al), oxygen (O), nitrogen (N), chromium (Cr), gold (Au), niobium (Nb), palladium (Pd), cobalt (Co), vanadium (V), nickel (Ni), platinum (Pt), titanium (Ti), tungsten (W), tantalum (Ta), or other materials. In various examples, the storage material 302 may include one or more chalcogenide materials such as such as Te—Se, Ge—Te, In—Se, Sb—Te, Ta—Sb—Te, As—Te, As—Se, Al—Te, As—Se—Te, Ge—Sb—Te, Ge—As—Se, Te—Ge—As, V—Sb—Se, Nb—Sb—Se, In—Sb—Te, In—Se—Te, Te—Sn—Se, V—Sb—Te, Se—Te—Sn, Ge—Se—Ga, Mo—Sb—Se, Cr—Sb—Se, Ta—Sb—Se, Bi—Se—Sb, Mo—Sb—Te, Ge—Bi—Te, W—Sb—Se, Ga—Se—Te, Ge—Te—Se, Cr—Sb—Te, Sn—Sb—Te, W—Sb—Te, As—Sb—Te, Ge—Te—Ti, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Se—Te—In, As—Ge—Sb—Te, Se—As—Ge—In, Ge—Sb—Se—Te, Ge—Sn—Sb—Te, Ge—Te—Sn—Ni, Ge—Te—Sn—Pd, and Ge—Te—Sn—Pt, Si—Ge—As—Se, In—Sn—Sb—Te, Ge—Se—Te—Si, Si—Te—As—Ge, Ag—In—Sb—Te, Ge—Se—Te—In—Si, or Se—As—Ge—Si—In. In other various examples, storage material 302 may include other materials capable of being programmed to one of multiple states, such as Ge—Sb, Ga—Sb, In—Sb, Sn—Sb—Bi, or In—Sb—Ge. One or more elements in a chalcogenide material (or other material used as storage material 302) may be dopants. For example, the storage material 302 may include dopants such as: aluminum (Al), oxygen (O), nitrogen (N), silicon (Si), carbon (C), boron (B), zirconium (Zr), hafnium (Hf), or a combination thereof. In some embodiments, the chalcogenide material (or other material used as storage material 302) may include additional elements such as hydrogen (H), oxygen (O), nitrogen (N), chlorine (Cl), or fluorine (F), each in atomic or molecular forms. The storage material 302 may include other materials or dopants not explicitly listed. In some examples, the storage material (such as any of the materials described above) is a phase change material. In other examples, the storage material 302 is not a phase change material, e.g., can be in one or multiple stable states (or transition between stable states) without a change in phase.

In some embodiments, a selector element coupled to storage material (e.g., in non-self-selecting memory cells) may also include a chalcogenide material. A selector device having a chalcogenide material can sometimes be referred to as an Ovonic Threshold Switch (OTS). An OTS may include a chalcogenide composition including any one of the chalcogenide alloy systems described above for the storage element and may further include an element that can suppress crystallization, such as arsenic (As), nitrogen (N), or carbon (C), to name a few. Examples of OTS materials include Te—As—Ge—Si, Ge—Te—Pb, Ge—Se—Te, Al—As—Te, Se—As—Ge—Si, Se—As—Ge—C, Se—Te—Ge—Si, Ge—Sb—Te—Se, Ge—Bi—Te—Se, Ge—As—Sb—Se, Ge—As—Bi—Te, and Ge—As—Bi—Se, among others.

In some embodiments, an element from column III of the periodic table (“Group III element”) may be introduced into a chalcogenide material composition to limit the presence of another material (e.g., Ge) in the selector device. For example, a Group III element may replace some or all of the other material (e.g., Ge) in the composition of the selector device. In some embodiments, a Group III element may form a stable, Group III element-centered tetrahedral bond structure with other elements (e.g., Se, As, and/or Si). Incorporating a Group III element into the chalcogenide material composition may stabilize the selector device to allow for technology scaling and increased cross point technology development (e.g., three-dimensional cross point architectures, RAM deployments, storage deployments, or the like).

In one embodiment, each selector device comprises a chalcogenide material having a composition of Se, As, and at least one of B, Al, Ga, In, and Tl. In some cases, the composition of the chalcogenide material comprises Ge or Si, or both.

In one example, the storage material is capable of switching between two or more stable states without changing phase (in other examples the storage material may switch between two stable states by changing phase). In one such embodiment, the access circuitry 342 programs the memory cell 300 by applying one or more program pulses (e.g., voltage or current pulses) with a particular polarity to cause the storage material 302 to be in the desired stable state. In one embodiment, the access circuitry 342 applies program pulses to the access lines 304, 306 (which may correspond to a bitline and a wordline) to write to or read the memory cell 300. In one embodiment, to write to the memory cell 300, the access circuitry applies one or more program pulses with particular magnitudes, polarities, and pulse widths to the access lines 304, 306 to program the memory cell 300 to the desired stable state, which can both select memory cell 300 and program memory cell 300. In various embodiments below, programming states are depicted as being associated with a single programming pulse, however, the single programming pulse may also be equivalent to a series of programming pulses that have the effective characteristics of the single programming pulse (e.g., a width of the single programming pulse may be equivalent to the sum of the widths of a series of shorter programming pulses).

In one embodiment, programming the memory cell 300 causes the memory cell 300 to “threshold” or undergo a “threshold event.” When a memory cell thresholds (e.g., during application of a program pulse), the memory cell undergoes a physical change that causes the memory cell to exhibit a certain threshold voltage in response to the application of a subsequent voltage (e.g., through application of a read pulse with a particular voltage magnitude and polarity). Programming the memory cell 300 can therefore involve applying a program pulse of a given polarity and application of current for a duration of time, which causes the memory cell 300 to exhibit a particular threshold voltage at a subsequent reading voltage of a same or different polarity. In one such embodiment, the storage material 302 is a self-selecting material that can be programmed by inducing a threshold event.

Access circuitry 342 may write to or read a memory cell 300 by applying one or more pulses having a particular magnitude, pulse width, and polarity (e.g., as defined by the program pulse parameters associated with the group to which the cell belongs) to the terminals (e.g., electrodes 308, 310) of the memory cell. The amplitude or width of a program pulse can vary depending on implementation, and can be, for example, somewhere between 1 and 60 MA/cm² and 1 nanosecond and 1 microsecond respectively. The pulse polarity may be positive or negative.

A positive programming pulse refers to a programming pulse with “positive polarity,” which can also be referred to as “forward polarity.” A negative programming pulse is a program pulse with “negative polarity,” which can also be referred to as “reverse polarity.” In one example, whether or not a programming pulse is positive or negative is based on the relative voltages applied to the terminals of the memory cell (e.g., 300). A program pulse can be defined as positive if the resulting voltage applied to one of the terminals is more positive than the voltage applied to a second of the terminals. For example, referring to FIG. 3, a positive program pulse can include: a positive voltage applied to electrode 308 and a negative voltage applied to electrode 310; a positive voltage applied to 308 and 0 V (e.g., circuit ground or neutral reference) applied to electrode 310; 0V applied to electrode 308 and a negative voltage applied to electrode 310, positive voltages applied to both electrodes 308 and 310, but where the voltage applied to electrode 308 is greater than the voltage applied to electrode 310; or negative voltages applied to both electrodes 308 and 310, but where the magnitude of the voltage applied to electrode 310 is greater than the magnitude of the voltage applied to electrode 308.

A program pulse applied to the terminals of the memory cell (e.g., 300) would be negative if the voltage applied to electrode 310 is more negative than the voltage applied to electrode 308. For example, a negative program pulse can include: a negative voltage applied to electrode 308 and a positive voltage applied to electrode 310; a negative voltage applied to electrode 308 and 0 V (e.g., circuit ground or neutral reference) applied to electrode 310; 0V applied to electrode 308 and a positive voltage applied to electrode 310, negative voltages applied to both electrodes 308 and 310, but where the magnitude of the voltage applied to electrode 308 is greater than the magnitude of the voltage applied to electrode 310; or positive voltages applied to both electrodes 308 and 310, but where the magnitude of the voltage applied to electrode 310 is greater than the magnitude of the voltage applied to electrode 308.

The program pulses can have any of a variety of shapes. For example, the program pulses may be box-shaped (also commonly referred to as rectangular-shaped or square-shaped), triangular (e.g., ramped), trapezoidal, rectangular, box, and/or sinusoidal pulses. In actual implementations, the program pulses may have leading or trailing edges. In some cases, the actual pulse shape may be the shape resulting from a discharge of transient current as governed by memory array and circuit parasitics. Thus, circuitry for accessing memory cells can apply programming pulses having a variety of shapes and durations sufficient to cause the memory cells to threshold into the desired state.

During a read operation, access circuitry 342 may determine a threshold voltage of a memory cell based on electrical responses to a read voltage applied to the memory cell. Detecting electrical responses can include, for example, detecting a voltage drop (e.g., a threshold voltage) across terminals of a given memory cell of the array or current through the given memory cell. In some cases, detecting a threshold voltage for a memory cell can include determining that the cell's threshold voltage is lower than or higher than a reference voltage, for example a read voltage. The access circuitry 342 can determine the logic state of the memory cell 300 based on the electrical response of the memory cell to the read voltage pulse.

As mentioned above, the access lines 304, 306 electrically couple the memory cell 300 with circuitry 342. The access lines 304, 306 can be referred to as a bitline and wordline, respectively. The wordline is for accessing a particular word in a memory array and the bitline is for accessing a particular bit in the word. The access lines 304, 306 can be composed of one or more metals including: Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicide nitrides including TiSiN and WSiN; conductive metal carbide nitrides including TiCN and WCN, or any other suitable electrically conductive material.

In one embodiment, electrodes 308 are disposed between storage material 302 and access lines 304, 306. Electrodes 308 electrically couple access lines 304, 306 to storage material 302. Electrodes 308 can be composed of one or more conductive and/or semiconductive materials such as, for example: carbon (C), carbon nitride (CₓN_{y}); n-doped polysilicon and p-doped polysilicon; metals including, Al, Cu, Ni, Mo, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicides nitrides including TiSiN and WSiN; conductive metal carbide nitrides including TiCN and WCN; conductive metal oxides including RuO₂, or other suitable conductive materials. In one embodiment, conductive wordline layer can include any suitable metal including, for example, metals including, Al, Cu, Ni, Mo, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicides nitrides including TiSiN and WSiN; conductive metal carbide nitrides including TiCN and WCN, or another suitable electrically conductive material.

The memory cell 300 is one example of a memory cell that may be used to store one or more logical bits. Other embodiments can include memory cells having additional or different layers of material than illustrated in FIG. 3 (e.g., a selection device between the access line 304 and the storage element, a thin dielectric material between the storage material and access lines, or other suitable configuration).

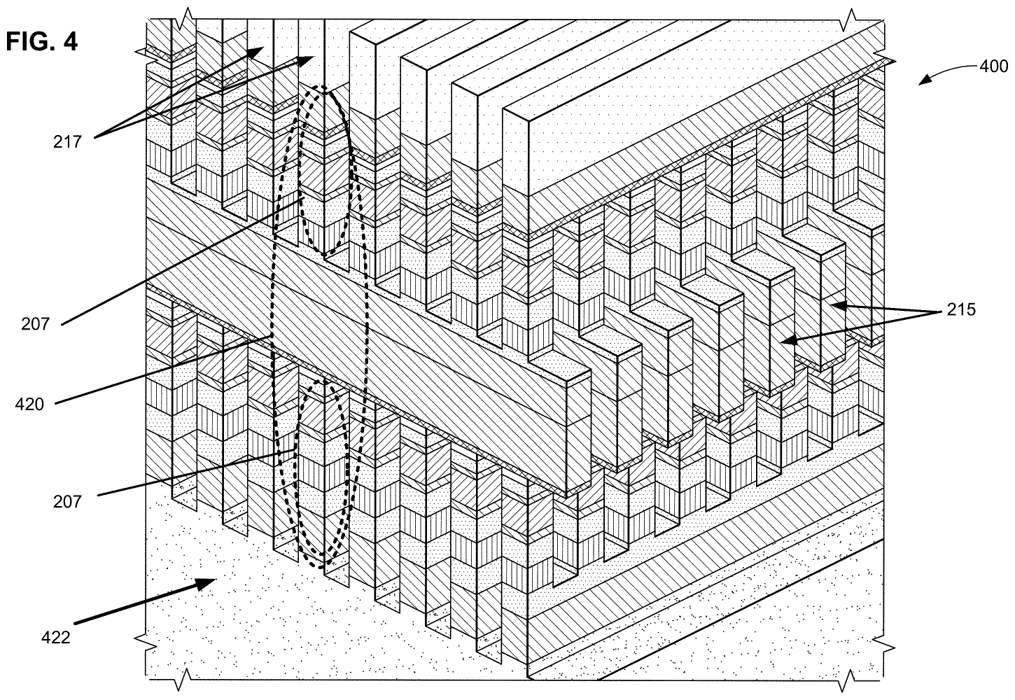

FIG. 4 is a perspective view of portions of a 3D crosspoint memory stack according to one embodiment. The specific layers are merely examples and will not be described in detail here. Stack 400 is built on substrate structure 422, such as silicon or other semiconductor. Stack 400 includes multiple pillars 420 as memory cell stacks of memory cells 207 or 300. In the diagram of stack 400, it will be observed that the WLs and BLs are orthogonal to each other, and traverse or cross each other in a cross-hatch pattern. A crosspoint memory structure includes at least one memory cell in a stack between layers of BL and WL. As illustrated, wordlines (WL) 215 are in between layers of elements, and bitlines (BL) 217 are located at the top of the circuit. Such a configuration is only an example, and the BL and WL structure can be swapped. Thus, in one representation of stack 400, the WLs can be the metal structures labeled as 217, and the BLs can be the metal structures labeled as 215. Different architectures can use different numbers of stacks of devices, and different configuration of WLs and BLs. It will be understood that the space between pillars 420 is typically an insulator.

Substrate structure 422, such as a silicon substrate, may include control circuitry therein (not shown), such as control circuitry including transistors, row decoders, page buffers, etc. The control circuitry of substrate structure 422 may include, for example, a memory partition controller such as memory partition controller 210, BL control logic such as BL control logic 216, and WL control logic such as WL control logic 214 of FIG. 2, access circuitry 342, or other suitable control circuitry. Each row of WLs 215 extending in the Y direction, the corresponding cells as coupled to corresponding BLs, would define a memory array, and may correspond to a memory array such as memory array 206 of FIG. 2.

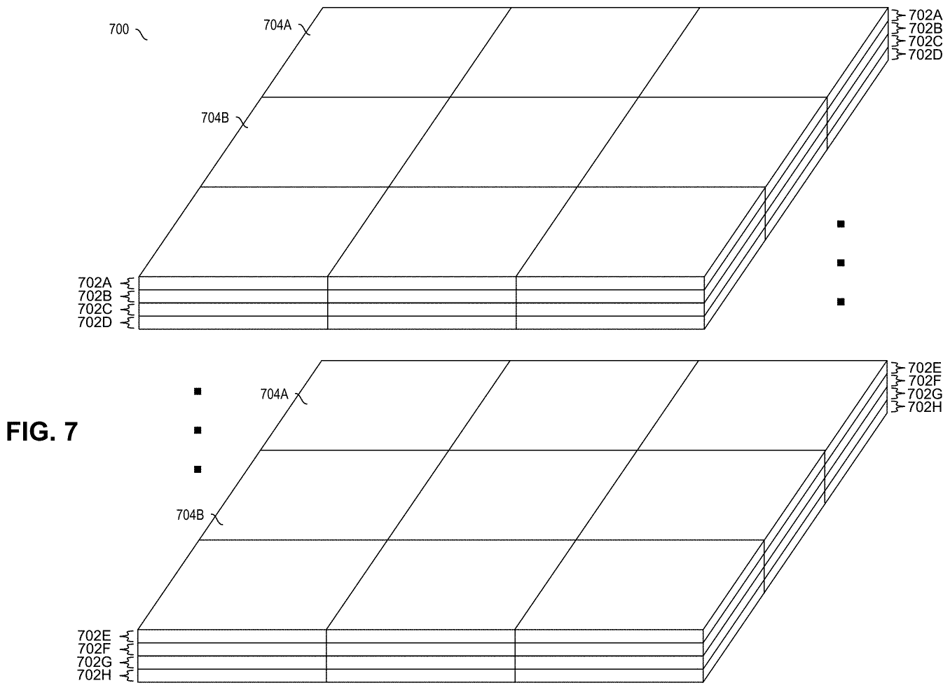

FIG. 5A illustrates an example tile and example threshold voltage distributions for memory cells at various tile coordinates in accordance with certain embodiments. A tile 502 represents a portion of a memory array (more details with respect to example tiles are given in connection with FIG. 7 below). Three groups of cells (A, B, and C) at different positions on the tile 502 are depicted. Memory cells in these tile groups may exhibit systematic differentials in response to the same program pulse. Example threshold voltage distributions of the groups are shown to the right of the tile 502. As depicted, for a first program state (e.g., where a logical value of one is stored by the memory cells), the threshold voltages of the cells in group A are (on average) lower than the threshold voltages of the cells in group B, which in turn are lower than the threshold voltages of the cells in region C. Similarly, for a second program state (e.g., where a logical value of zero is stored by the memory cells), the threshold voltages of the cells in group A are again lower than the threshold voltages of the cells in group B, which in turn are lower than the threshold voltages of the cells in group C.

The differences in the distributions may be due to cross-tile effects that reflect program state non-uniformity across the memory array as caused by cell-circuit interactions due to distributed parasitic networks from decoders and/or other factors (such as differing resistances and capacitances associated with the memory cells).

FIG. 5B illustrates threshold voltages of example groups of cells A′, B′, and C′ with different cycle counts in accordance with certain embodiments. Graph 504 shows that (for a particular memory array), threshold voltages of cells programmed to a particular program state may drop (on average) as cycle counts increase (where a cycle count may represent the number of times the cell has been written to and/or read from). Example threshold voltage distributions of the groups are shown to the right of the graph 504. As depicted, for a first program state, the threshold voltages of the C′ cells are (on average) lower than the threshold voltages of the B′ cells which in turn are lower than the threshold voltages of the A′ cells. For a second program state, a similar relationship exists among the threshold voltages of the cells. Although the threshold voltages are shown as decreasing as the number of cycles increase in FIG. 5B, in other embodiments the threshold voltages could increase or stay constant as the cycles increase (e.g., different material stacks used in the memory cells may respond differently to increasing cycles).

FIGS. 5A and 5B illustrate that the distribution of threshold voltages for cells with similar characteristics (e.g., any of the individual distributions shown) is narrower than the overall distributions (e.g., 501, 503, 505, 507) of threshold voltages among cells having different characteristics. As the distributions widen due to varying characteristics of the cell across the memory array, the respective read window budgets may shrink.

FIG. 5C illustrates an example intrinsic read window budget 510 and net read window budget 516 between program states in accordance with certain embodiments. The intrinsic read window budget 510 is the margin between the end of the intrinsic distribution 506 of threshold voltages in a first program state (‘1’) and the start of the intrinsic distribution 508 of threshold voltages in a second program state (‘0’). The intrinsic distributions may represent distributions of threshold voltages in cells due solely to manufacturing process differences in the cells themselves rather than other characteristics associated with the cells (e.g., the cells' relative placement within the array or the cycle count of the cells). Actual distributions 512 and 514 take into account these additional characteristics. Because the actual distributions are wider than the intrinsic distributions, the net read window budget 516 is smaller than the intrinsic read window budget 510. Various embodiments of the present disclosure reduce the size of the threshold voltage distributions across groups of cells array locations, cycle counts, and/or operating temperatures by shifting the distributions of groups of memory cells by using customized programming pulses taking into account the program response of the cells to improve the size of the read window budget.

FIG. 5D illustrates example cell program responses in accordance with certain embodiments. Different compositions of memory cells (e.g., where a memory cell may utilize a certain material for the storage element of the cell) may exhibit different programming characteristics. In the example depicted in graph 518, given a common program pulse width, a memory cell comprising material A has a threshold voltage that increases as the pulse amplitude of a program pulse increases, a material B has a threshold voltage that drops as the pulse amplitude increases, and a material C has a threshold voltage that stays constant as the pulse amplitude increases. In the example depicted in graph 520, given a common program pulse amplitude, a material D has a threshold voltage that increases as the pulse width of a program pulse increases, a material E has a threshold voltage that decreases as the pulse width increases, and a material F has a threshold voltage that stays constant as the pulse width increases. A particular material could have any of the characteristics shown in graph 518 and any of the characteristics shown in graph 520 (or may exhibit other suitable programming behavior, such as non-linear rise or drop, based on the program pulse amplitude and width).

The program levels (e.g., threshold voltages) of the memory cells of a particular array may be tuned based on their programming response to pulse amplitude and pulse width. For example, if a particular group of memory cells exhibits (or is expected to exhibit) a threshold voltage distribution that is higher than desired when programmed to a particular state (e.g. using a default program pulse), program pulse parameters for the program pulse used to program that group of cells to that state may be tuned to cause the group of memory cells to exhibit a lower threshold voltage distribution (e.g., by changing the program pulse amplitude and/or pulse width). By systematically adjusting the program pulse parameters for various groups of memory cells in the memory array, a wider read window budget may be achieved by tightening the distributions of the threshold voltages of the various program states.

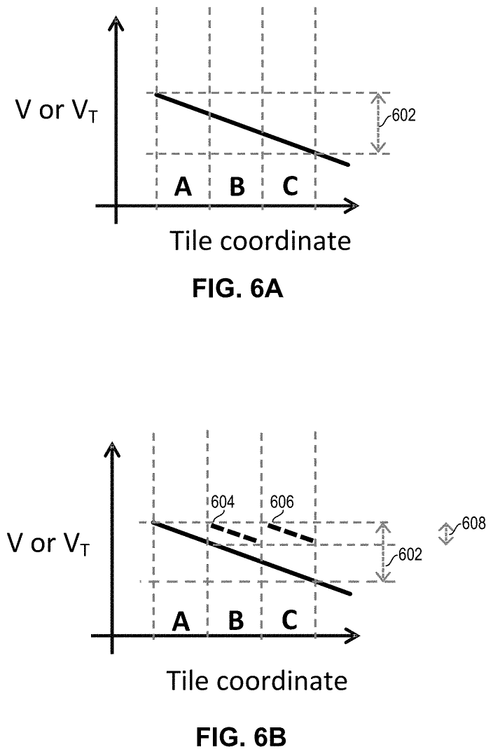

FIGS. 6A-6B illustrate example untuned and tuned memory cell threshold voltages as a function of tile coordinate in accordance with certain embodiments. In FIG. 6A, the threshold voltages of the cells decrease in region B relative to region A and again in region C relative to region B. Thus, the width of the combined threshold voltage distribution of the cells in regions A, B, and C is depicted by 602.

FIG. 6B includes the same graph as FIG. 6A, but also includes overlays of tuned threshold voltages for the cells of regions B and C (overlay 604 represents tuned threshold voltages for region B and overlay 606 represents tuned threshold voltages for region C). The tuning may be achieved by defining programming pulse parameters for the program pulse that is applied to cells of region B and also defining programming pulse parameters for the program pulse that is applied to cells of region C in order to shift the distributions of the threshold voltages higher in order to be similar to the distribution of threshold voltages of the cells of region A. For example, the program pulse used to program cells of region B may be different (e.g., in amplitude and/or pulse width) from the program pulse used to program cells of region A, and the program pulse used to program cells of region C may be different from the program pulse used to program cells of region A and the program pulse used to program cells of region B.

The program pulse parameters are defined based on the program response of the memory cells to various pulse amplitudes and/or pulse widths (e.g., as depicted in FIG. 5D). For example, for memory cells comprising material A in FIG. 5D, in order to achieve the tuning shown in FIG. 6B and assuming the program pulse widths are equal, the program pulse applied to cells of region B may have a higher amplitude than the program pulse applied to cells of region A, and the program pulse applied to cells of region C may have a higher amplitude than the program pulse applied to cells of region B. As another example, for memory cells comprising material E in FIG. 5D, in order to achieve the compensations shown in FIG. 6B and assuming that the program pulse amplitudes are equal, the program pulse applied to cells of region B may have a shorter pulse width than the program pulse applied to cells of region A, and the program pulse applied to cells of region C may have a shorter pulse width than the program pulse applied to cells of region B. In other embodiments, both the pulse amplitude and pulse width may vary from group to group.

FIG. 7 illustrates a 3D crosspoint memory array arranged into decks 702 (e.g., 702A-702H) and tiles 704 (e.g., 704A and 704B) in accordance with certain embodiments. A deck 702 includes a layer of memory cells and supporting circuitry of a memory array. For example, referring back to FIG. 4, a deck 702 may comprise all of the memory cells 207 in a horizontal plane of the array between a set of row address lines (e.g., wordlines) 215 and a set of column address lines (e.g., bitlines) 217. As depicted, the decks are stacked in a vertical direction in top of each other. Although not shown, any number of decks may be present between deck 702D and 702E or the array may include less decks than is shown. In various embodiments, a memory array may include any suitable number of decks, such as one, two, four, six, or other suitable number of decks. A pillar 420 of memory cell stacks may include a memory cell stack from each of a plurality of the decks 702.

A tile 704 may include a collection of bitlines and wordlines that have a common set of local decoders and the memory cells coupled to those bitlines and wordlines. In various embodiments, a memory array may be partitioned into tiles 704 in order to reduce the length of the bitlines and wordlines (otherwise the bitlines and wordlines would span the entire length and width of the array). The partition of the memory array into tiles also provides for memory parallelism (e.g., a cell on each tile 704 of a particular deck 702 may be accessed simultaneously for a read or write operation). In some embodiments, the pattern of a tile may be replicated across the array. For example, the pattern used for tile 704A of deck 702A may be replicated in the other decks in the same location within each deck (e.g., in the embodiment depicted tile 704A is shown as being replicated in deck 702A and in 702E). In some embodiments, the same pattern for a tile may be replicated across the same deck (e.g., the nine tiles shown for deck 702A may all have the same pattern of wordlines and bitlines). In some embodiments, the tiles may differ at least in part (e.g., in size and/or structure). In various embodiments (e.g., as depicted), the tiles of the various decks are stacked on top of each other, though in other embodiments, the tiles may be staggered (e.g., the decks may be interleaved), e.g., in order to allow space to route vias to the upper tiles.

In various embodiments, the tiles may be split into groups of memory cells and these groups may be applied to other tiles of the same deck. For example, the memory cells of tile 704A of deck 702A may be split into ten groups (or other number of groups) and the memory cells of the other tiles 704 of deck 702A may be split similarly. Thus, a first group may include cells from a particular region (e.g., particular row and column address combinations) of tile 704A, cells from the same region of tile 704B, and cells from that region on each of the other tiles of deck 702A. A second group could then include cells from a different region on all of the tiles of deck 702A (e.g., the same region on each tile of deck 702A), and so on. In various embodiments, the groups may span more than one deck. For example, the first group referenced earlier could also include cells from the same region of tile 704A of deck 702E (and other tiles of that deck or other decks). Alternatively, the first group could include cells from some different region of one or more tiles of a different deck. Thus, in some embodiments, a deck 702 may include cells assigned to a group that also includes cells of another deck. In other embodiments, cells of each deck 702 may be assigned to groups that are specific to the respective deck and independent of the groups of the other decks (such that each group only includes cells from one of the decks). In various embodiments, the number of groups used for each deck may be the same (e.g., 10 each) or the number of groups used for the decks may vary (e.g., one deck may be divided into 10 groups while another deck may be divided into 6 groups).

The determination of the program pulse parameters for the various groups of cells can be either a-priori, e.g. all the dies manufactured can inherit the same pulse parameters (e.g., based on prior characterization, simulations, or calculations) or the program pulse parameters can be determined during manufacturing (e.g., each die may be tested individually during manufacturing to determine the optimal pulse parameters). Thus, for example, at the time of manufacturing (or other suitable time), various memory cells of a memory array may be tested to determine their program response to various program pulses (e.g., to determine the threshold voltages the cells have after the various program pulses have been applied). Based on these program responses, the cells may be grouped and/or program pulse parameters specific to each group may be defined for each program state (e.g., 0 and 1 states for single level cells; 00, 01, 10, and 11 states for multi-level cells, 000, 001, 010, 011, 100, 101, 110, and 111 states for tri-level cells, and so on). As another example, information from the design of the memory array may be used to select the groups and/or define the program pulses for the groups. For example, expected resistances on the respective bitlines and wordlines of the cells could be used alone or in combination with expected capacitances between bitlines and wordlines of the cells to characterize the expected responses of memory cells and the expected responses may be used to group the memory cells and/or assign program pulse parameters to each group. In various embodiments, at the time of manufacturing (or any other suitable time) one or more memory arrays (e.g., of one or more dies) may be characterized (e.g., by determining program responses to various cells of the tile). The characterizations may then be used to assign groups and/or define program pulses for the groups for other dies manufactured using the same process.

The groups may be organized in any suitable fashion. For example, the groups may be organized based on row and column addresses of the cells. As one example, if a tile layout is comprising 4 k rows and 4 k columns, there would be a maximum of 4 k×4 k cell positions for that particular tile 704 within a particular deck 702. In one embodiment, these cells may be split into various groups according to their row and column addresses. As just one example, an address summing scheme could be used to split the groups up. For example, a first group may comprise all memory cells where the row_address+column_address<512, a second group may comprise all memory cells where 512<=the row_address+column_address<1024, and so on until the final group comprises all memory cells where 7680<=row_address+column_address<8192.

In another example, a cell may be placed in a group based on the resistance from a wordline driver to a first terminal of the cell plus the resistance from a second terminal of the cell to a bitline driver. For example, if such a resistance is estimated to be less than 1K Ohm, the cell may be assigned to a first group, if such a resistance is estimated to be between 1K and 5K Ohm, the cell may be assigned to a second group, and so on. In some embodiments, the sum of the row and column address (e.g., as described in the preceding paragraph) may be used as a proxy for the resistance.

The assignments of memory cells to the groups and the program pulse parameters may be stored or configured in any suitable manner. For example, hardware of a memory array (e.g., one or more of memory partition controller 210, chip controller 126, or storage device controller 118) may include circuitry to store the groupings and associated program pulse characteristics and allow the determination of such for a memory cell to be programmed. In some embodiments, such circuitry may include one or more lookup tables. In various embodiments, the pulse parameters may be programmable (and thus could be modified at any suitable time). In some embodiments, the program pulse parameters may be implemented in a die with fuses that are fused out during the manufacturing process and then copied to SRAM or other fast memory for use during operation. In other embodiments, the parameters may be updated after manufacturing, e.g., by enabling the die to self-correct based on customer operation or using self-test functions that are performed during customer operation.

The program pulse parameters may be stored in any suitable format. For example, the actual values of the parameters may be stored. Thus, a set of program pulse parameters could include a program pulse amplitude (e.g., in terms of micro Amperes) and a program pulse width (e.g., in terms of nanoseconds). As another example, the program pulse parameters may be stored as representations of the actual values. For example, a pulse parameter may be stored as a value that is to be multiplied by another value or added to another value (such as a default pulse parameter value).

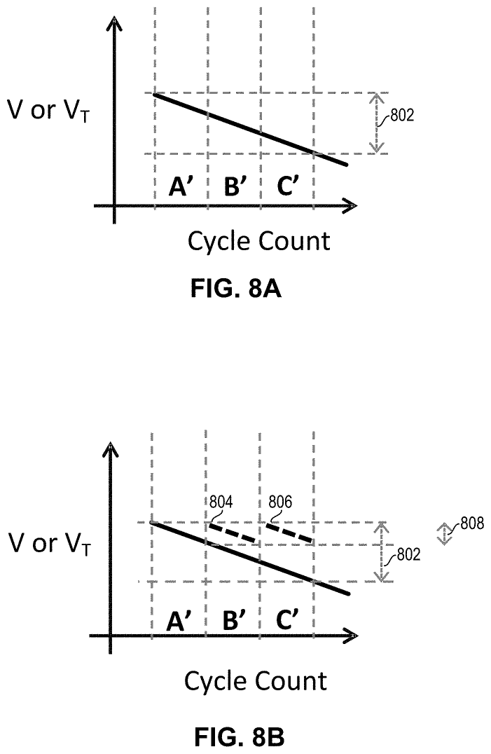

FIGS. 8A-8B illustrate example untuned and tuned memory cell threshold voltages as a function of cycle count in accordance with certain embodiments. The FIGS. illustrate threshold voltages for three groupings (A′, B′, and C′) of memory cells having different numbers of cycle counts. In the embodiment depicted, the cycle counts of the cells in A′ are less than the cycle counts of the cells in B′, which in turn are less than the cycle counts of the cells in C′. As FIG. 8A shows, as the program pulse characteristics are held constant, the threshold voltages of the memory cells may increase with increasing cycle counts. In FIG. 8A, the threshold voltages of the cells decrease in group B′ relative to group A′ and again in group C′ relative to group B′. Thus, the width of the combined threshold voltage distribution of the cells in regions A, B, and C is depicted by 802.

In other embodiments, different relationships may exist between the threshold voltages and the cycle counts. For example, threshold voltages could decrease with increasing cycle counts or may stay constant with increasing cycle counts (in which case tuning would not be needed for different cycle counts). As another example, the threshold voltages could exhibit a non-linear relationship with respect to the cycle counts.

FIG. 8B includes the same graph as FIG. 8A, but also includes overlays of tuned threshold voltages for the cells of groups B′ and C′ (overlay 804 represents tuned threshold voltages for group B′ and overlay 806 represents tuned threshold voltages for group C′). The tuning may be achieved by defining the parameters of a programming pulse that is applied to cells of group B′ and also by defining the parameters of a program pulse that is applied to cells of group C′ in order to shift the distributions of the threshold voltages to be similar to the distribution of threshold voltages of the cells of group A′. For example, the program pulse used to program cells of group B′ may be different (e.g., in amplitude and/or pulse width) from the program pulse used to program cells of group A′, and the program pulse used to program cells of group C′ may be different from the program pulse used to program cells of group A′ and the program pulse used to program cells of group B′.

The program pulse parameters may be defined based on the program response of the memory to varied pulse amplitudes and/or pulse widths (e.g., as depicted in FIG. 5D) in order to provide tuning for various cycle counts of the memory cells. For example, for memory cells comprising material A in FIG. 5D, in order to achieve the compensations shown in FIG. 8B and assuming the program pulse widths are equal, the program pulse applied to cells of group B′ may have a higher amplitude than the program pulse applied to cells of group A′, and the program pulse applied to cells of group C′ may have a higher amplitude than the program pulse applied to cells of group B′. As another example, for memory cells comprising material E in FIG. 5D, in order to achieve the compensations shown in FIG. 8B and assuming that the program pulse amplitudes are equal, the program pulse applied to cells of group B′ may have a shorter pulse width than the program pulse applied to cells of group A′, and the program pulse applied to cells of group C′ may have a shorter pulse width than the program pulse applied to cells of group B′. In other embodiments, instead of only varying one of the pulse amplitude or pulse width in order to tune the threshold voltage of the cells, both the pulse amplitude and pulse width may be varied for one or more particular groups of cells.

In a particular embodiment, a hardware controller (e.g., one or more of memory partition controller 210, chip controller 126, or storage device controller 118) may track the current level of wear leveling for the various memory cells. The controller may also be responsible for controlling the locations of writes in an attempt to bring all of the cells within a given range of wear. The controller may also update the program pulse parameters based on the current level of wear of groups of cells.

In various embodiments, the same groups that are used for tuning the cells based on cross tile effects may also be used to tune the cells based on cycle counts. In other embodiments, groups used for tuning the cells based on cycle counts may be independent of groups used for tuning the cells based on cross tile effects. For example, if different groupings were used to tune for cross tile effects and cycle count effect, the actual programming pulse characteristics could be based on the program pulse parameters assigned to each group. As another example, some embodiments may omit the tuning of cross tile effects and only including groupings for cycle count tuning.

The program pulse parameters may be based on one or more cycle count thresholds. For example, the program pulse parameters for a group of cells may be adjusted when one or more cycle count thresholds are crossed (or not crossed). A cycle count threshold may be specified in any suitable manner. For example, a cycle count threshold may apply to all cells or to a subset (e.g., the most cycled or the least cycled) of a group, a deck, or the entire memory array.

In various embodiments, when one or more cycle count thresholds is crossed, one or more of the program pulse parameters may be adjusted (to either increase the programmed threshold voltages or decrease the programmed threshold voltages depending on the expected effect on the program response of the cells).

In some embodiments, once a cycle count threshold applicable to an entire deck is crossed, one or more program pulse parameters for each group having cells that are part of that deck may be adjusted accordingly. Such adjustments could also be made responsive to crossings of additional cycle count thresholds. The adjustments may or may not be uniform across the groups. For example, a pulse amplitude for each group could be adjusted by the same amplitude. As another example, a particular pulse amplitude of a particular group may be adjusted by a different amplitude than another particular group. As another example, a program pulse parameter of a particular group may be adjusted in a certain direction (e.g., the pulse amplitude may be increased or the pulse width may be lengthened) while a program pulse parameter of another group may be adjusted in the opposite direction (e.g., the pulse amplitude may be decreased or the pulse width may be shortened).

In various embodiments, the adjustment of the program pulse parameters (of a group, groups of a deck, or all groups) may be governed by multiple different cycle thresholds (e.g., a threshold applying to the most cycled cells of a group, groups of a deck, or the entire array and a threshold applying to the least cycled cells of a group, groups of a deck, or the entire array).

As just one example, when a group of cells all have cycle counts that are less than 50 k cycles, then initial pulse program parameters may be used when writing to the cells. When the most cycled cells of the group have gone past 50 k cycles and the least cycled cells of the group are at least at 10 k cycles, then a second set of pulse parameters may be used for the group. When the most cycled cells have gone past 100 k cycles, and the least cycled cells are at least at 30 k cycles, then a third set of pulse parameters may be used for the group.

In various embodiments, the adjustment of the program pulse parameters (e.g., of a group, all or certain groups of a deck, or all groups of a partition) may be based on an operating temperature associated with a memory chip 116 or the particular partition 122 (e.g., an operating temperature measured at a particular location of the memory chip 116 or at a particular location of a partition 122). For example, when the memory chip 116 (or a particular partition 122) is operating within a first range of operating temperatures, an adjustment may be made to one or more of the program pulse parameters (e.g., to either increase the programmed threshold voltages or decrease the programmed threshold voltages depending on the expected effect of the temperature on the program response of the cells). When the memory chip 116 (or partition 122) is operating with a second range of operating temperatures, a different adjustment may be made to one or more of the program pulse parameters. According to some implementations, an adjustment of the demarcation read voltage may also be made as function of temperature (e.g. reduced at given mV/° C. rate as temperature is increased) as an additional or alternative method for optimizing read window budget operation.

The adjustment made to the one or more program pulse parameters based on the operating temperature may be uniform across the partition (e.g., the same amount of adjustment may be made for every program state and for every group of every deck) or could be different (e.g., different amounts of adjustment may be made for different program states, different groups, or different decks) depending on the characteristics of the memory.

As just one example, when the operating temperature is less than a first temperature, then the program pulse parameters may be unaffected (e.g., the parameters could be based solely on the grouping and/or cycle counts of the cells). When the operating temperature is equal to or greater than the first temperature but less than a second temperature, then the program pulse parameters may be adjusted (e.g., uniformly or different program pulse parameter sets may be adjusted by different amounts), where the adjustments may be made in addition to any adjustments based on the grouping or cycle counts as described above. When the operating temperature is equal to or greater than the second temperature but less than a third temperature, then the program pulse parameters may be adjusted differently, and so on.

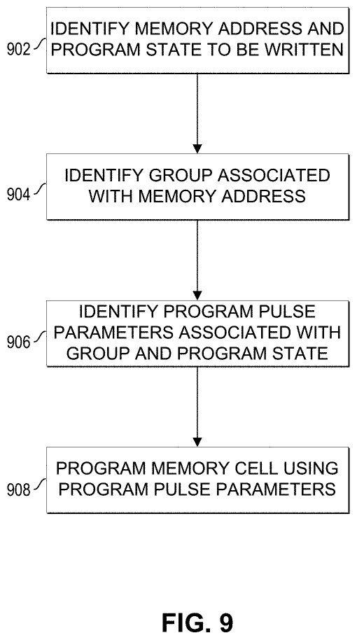

FIG. 9 illustrates a flow for programming a memory cell of a memory array in accordance with certain embodiments. At 902 a memory address of a cell to be written to and the program state to be written to the cell are identified. At 904, a group associated with the memory address is identified. At 906, a program pulse that is associated with the group and the program state is identified. At 908, the memory cell is programmed with a program pulse having the identified program pulse parameters.

The flows described in FIGS. 6, 8, and 9 are merely representative of operations that may occur in particular embodiments. Some of the operations illustrated in the FIGs. may be repeated, combined, modified, or deleted where appropriate. Additionally, operations may be performed in any suitable order without departing from the scope of particular embodiments.

A design may go through various stages, from creation to simulation to fabrication. Data representing a design may represent the design in a number of manners. First, as is useful in simulations, the hardware may be represented using a hardware description language (HDL) or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In some implementations, such data may be stored in a database file format such as Graphic Data System II (GDS II), Open Artwork System Interchange Standard (OASIS), or similar format.

In some implementations, software based hardware models, and HDL and other functional description language objects can include register transfer language (RTL) files, among other examples. Such objects can be machine-parsable such that a design tool can accept the HDL object (or model), parse the HDL object for attributes of the described hardware, and determine a physical circuit and/or on-chip layout from the object. The output of the design tool can be used to manufacture the physical device. For instance, a design tool can determine configurations of various hardware and/or firmware elements from the HDL object, such as bus widths, registers (including sizes and types), memory blocks, physical link paths, fabric topologies, among other attributes that would be implemented in order to realize the system modeled in the HDL object. Design tools can include tools for determining the topology and fabric configurations of system on chip (SoC) and other hardware device. In some instances, the HDL object can be used as the basis for developing models and design files that can be used by manufacturing equipment to manufacture the described hardware. Indeed, an HDL object itself can be provided as an input to manufacturing system software to cause the described hardware.

In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable storage medium, at least temporarily, an article, such as information encoded into a carrier wave, embodying techniques of embodiments of the present disclosure.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Logic may be used to implement any of the functionality of the various components such as CPU 102, external I/O controller 104, processor 108, cores 114A and 114B, I/O controller 110, CPU memory controller 112, storage device 106, system memory device 107, memory chip 116, storage device controller 118, address translation engine 120, memory partition 122, program control logic 124, chip controller 126, memory partition controller 210, wordline control logic 214, bitline control logic 216, WL switch circuitry 220, BL switch circuitry 224, access circuitry 342, or other entity or component described herein, or subcomponents of any of these. “Logic” may refer to hardware, firmware, software and/or combinations of each to perform one or more functions. In various embodiments, logic may include a microprocessor or other processing element operable to execute software instructions, discrete logic such as an application specific integrated circuit (ASIC), a programmed logic device such as a field programmable gate array (FPGA), a storage device containing instructions, combinations of logic devices (e.g., as would be found on a printed circuit board), or other suitable hardware and/or software. Logic may include one or more gates or other circuit components. In some embodiments, logic may also be fully embodied as software. Software may be embodied as a software package, code, instructions, instruction sets and/or data recorded on non-transitory computer readable storage medium. Firmware may be embodied as code, instructions or instruction sets and/or data that are hard-coded (e.g., nonvolatile) in storage devices.

Use of the phrase ‘to’ or ‘configured to,’ in one embodiment, refers to arranging, putting together, manufacturing, offering to sell, importing, and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘capable of/to,’ and or ‘operable to,’ in one embodiment, refers to some apparatus, logic, hardware, and/or element designed in such a way to enable use of the apparatus, logic, hardware, and/or element in a specified manner. Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example, the decimal number ten may also be represented as a binary value of 1010 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, e.g. reset, while an updated value potentially includes a low logical value, e.g. set. Note that any combination of values may be utilized to represent any number of states.

The embodiments of methods, hardware, software, firmware, or code set forth above may be implemented via instructions or code stored on a machine-accessible, machine readable, computer accessible, or computer readable medium which are executable by a processing element. A non-transitory machine-accessible/readable medium includes any mechanism that provides (e.g., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash storage devices; electrical storage devices; optical storage devices; acoustical storage devices; other form of storage devices for holding information received from transitory (propagated) signals (e.g., carrier waves, infrared signals, digital signals); etc., which are to be distinguished from the non-transitory mediums that may receive information there from.

Instructions used to program logic to perform embodiments of the disclosure may be stored within a memory in the system, such as DRAM, cache, flash memory, or other storage. Furthermore, the instructions can be distributed via a network or by way of other computer readable media. Thus a The machine-readable storage medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage medium used in the transmission of information over the Internet via electrical, optical, acoustical or other forms of propagated signals (e.g., carrier waves, infrared signals, digital signals, etc.). Accordingly, the computer-readable medium includes any type of tangible machine-readable storage medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

Example 1 may include a memory device including a three dimensional crosspoint memory array comprising memory cells assigned to a plurality of groups, wherein each group is associated with a respective at least one program pulse parameter based on programming responses of memory cells of that group; and access circuitry to program a memory cell of a first group of the plurality of groups to a first program state by applying a program pulse having the at least one program pulse parameter associated with the first group.

Example 2 may include the subject matter of Example 1, wherein the at least one program pulse parameter associated with a second group of the plurality of groups is to cause a distribution of threshold voltages of memory cells of the second group programmed to the first program state to align more closely with a distribution of threshold voltages of memory cells of the first group programmed to the first program state than if a default program pulse had been used to program the memory cells of the second group to the first program state.

Example 3 may include the subject matter of any one of Examples 1-2, wherein the memory cells are assigned to the plurality of groups based at least in part on locations of the memory cells within the three dimensional crosspoint memory array.

Example 4 may include the subject matter of any one of Examples 1-3, wherein the at least one program pulse parameter associated with the first group is based at least in part on a number of cycle counts of memory cells of the first group.

Example 5 may include the subject matter of any one of Examples 1-4, wherein the at least one program pulse parameter associated with the first group is based at least in part on an operating temperature associated with the memory device.

Example 6 may include the subject matter of any one of Examples 1-5, wherein the respective at least one program pulse parameter comprises an indication of an amplitude of a program pulse.

Example 7 may include the subject matter of any one of Examples 1-6, wherein the respective at least one program pulse parameter comprises an indication of a pulse width of a program pulse.

Example 8 may include the subject matter of any one of Examples 1-7, wherein the at least one program pulse parameter for each group includes a first program pulse parameter set for a first program state and a second program pulse parameter set for a second program state; and the access circuitry is to program the memory cell of the first group to the first program state by applying a program pulse in accordance with the first program pulse parameter set and to program the memory cell of the first group to a second program state by applying a program pulse in accordance with the second program pulse parameter set.

Example 9 may include the subject matter of any one of Examples 1-8, wherein the three dimensional crosspoint memory array comprises a plurality of stacked decks, a first subset of groups of the plurality of groups is specific to a first deck of the plurality of stacked decks, and a second subset of groups of the plurality of groups is specific to a second deck of the plurality of stacked decks.

Example 10 may include the subject matter of any one of Examples 1-9, wherein the memory cell comprises a first layer of chalcogenide material to function as a selector device and a second layer of chalcogenide material to function as a storage element.

Example 11 may include the subject matter of any one of Examples 1-10, wherein the memory cell comprises a chalcogenide material to function as both a selector device and a storage element.

Example 12 may include the subject matter of any one of Examples 1-11, wherein a threshold voltage tunability of the first program state of the memory cell is between 50 mV and 1500 mV.

Example 13 may include the subject matter of any one of Examples 1-12, further comprising a plurality of memory chips, wherein a first memory chip of the plurality of memory chips comprises the three dimensional crosspoint memory array and access circuitry.

Example 14 may include the subject matter of Example 13, further comprising a memory controller to communicate with the plurality of memory chips.

Example 15 may include the subject matter of any one of Examples 1-14, wherein the memory device comprises a solid state drive.

Example 16 may include the subject matter of any one of Examples 1-14, wherein the memory device comprises a dual in-line memory module.

Example 17 may include a method comprising associating memory cells of a three dimensional crosspoint memory array with a plurality of groups, wherein each group is associated with a respective at least one program pulse parameter based on programming responses of memory cells of that group; and programming a memory cell of a first group of the plurality of groups to a first program state by applying a program pulse having the at least one program pulse parameter associated with the first group.

Example 18 may include the subject matter of Example 17, wherein the at least one program pulse parameter associated with a second group of the plurality of groups is to cause a distribution of threshold voltages of memory cells of the second group programmed to the first program state to align more closely with a distribution of threshold voltages of memory cells of the first group programmed to the first program state than if a default program pulse had been used to program the memory cells of the second group to the first program state.

Example 19 may include the subject matter of any one of Examples 17-18, wherein the memory cells are assigned to the plurality of groups based at least in part on locations of the memory cells within the three dimensional crosspoint memory array.

Example 20 may include the subject matter of any one of Examples 17-19, wherein the at least one program pulse parameter associated with the first group is based at least in part on a number of cycle counts of memory cells of the first group.

Example 21 may include the subject matter of any one of Examples 17-20, wherein the at least one program pulse parameter associated with the first group is based at least in part on an operating temperature associated with the memory array.

Example 22 may include the subject matter of any one of Examples 17-21, wherein the respective at least one program pulse parameter comprises an indication of an amplitude of a program pulse.

Example 23 may include the subject matter of any one of Examples 17-22, wherein the respective at least one program pulse parameter comprises an indication of a pulse width of a program pulse.

Example 24 may include the subject matter of any one of Examples 17-23, wherein the at least one program pulse parameter for each group includes a first program pulse parameter set for a first program state and a second program pulse parameter set for a second program state; and the access circuitry is to program the memory cell of the first group to the first program state by applying a program pulse in accordance with the first program pulse parameter set and to program the memory cell of the first group to a second program state by applying a program pulse in accordance with the second program pulse parameter set.

Example 25 may include the subject matter of any one of Examples 17-24, wherein the three dimensional crosspoint memory array comprises a plurality of stacked decks, a first subset of groups of the plurality of groups is specific to a first deck of the plurality of stacked decks, and a second subset of groups of the plurality of groups is specific to a second deck of the plurality of stacked decks.

Example 26 may include the subject matter of any one of Examples 17-25, wherein the memory cell comprises a first layer of chalcogenide material to function as a selector device and a second layer of chalcogenide material to function as a storage element.

Example 27 may include the subject matter of any one of Examples 17-26, wherein the memory cell comprises a chalcogenide material to function as both a selector device and a storage element.

Example 28 may include the subject matter of any one of Examples 17-27, wherein a threshold voltage tunability of the first program state of the memory cell is between 50 mV and 1500 mV.

Example 29 may include the subject matter of any one of Examples 17-28, wherein a first memory chip of a plurality of memory chips comprises the three dimensional crosspoint memory array and access circuitry.

Example 30 may include the subject matter of Example 29, further comprising using a memory controller to communicate with the plurality of memory chips.

Example 31 may include the subject matter of any one of Examples 17-30, wherein the three dimensional crosspoint array is included within a solid state drive.

Example 32 may include the subject matter of any one of Examples 17-30, wherein the three dimensional crosspoint array is included within a dual in-line memory module.

Example 33 may include a system comprising a storage device controller; and at least one memory chip coupled to the storage device controller, wherein a memory chip comprises a three dimensional crosspoint memory array comprising memory cells assigned to a plurality of groups, wherein each group is associated with a respective at least one program pulse parameter based on programming responses of memory cells of that group; and access circuitry to program a memory cell of a first group of the plurality of groups to a first program state by applying a program pulse having the at least one program pulse parameter associated with the first group.

Example 34 may include the subject matter of Example 33, wherein the at least one program pulse parameter associated with a second group of the plurality of groups is to cause a distribution of threshold voltages of memory cells of the second group programmed to the first program state to align more closely with a distribution of threshold voltages of memory cells of the first group programmed to the first program state than if a default program pulse had been used to program the memory cells of the second group to the first program state.

Example 35 may include the subject matter of any one of Examples 33-34, wherein the memory cells are assigned to the plurality of groups based at least in part on locations of the memory cells within the three dimensional crosspoint memory array.

Example 36 may include the subject matter of any one of Examples 33-35, wherein the at least one program pulse parameter associated with the first group is based at least in part on a number of cycle counts of memory cells of the first group.

Example 37 may include the subject matter of any one of Examples 33-36, wherein the at least one program pulse parameter associated with the first group is based at least in part on an operating temperature associated with the memory chip.

Example 38 may include the subject matter of any one of Examples 33-37, wherein the respective at least one program pulse parameter comprises an indication of an amplitude of a program pulse.

Example 39 may include the subject matter of any one of Examples 33-38, wherein the respective at least one program pulse parameter comprises an indication of a pulse width of a program pulse.

Example 40 may include the subject matter of any one of Examples 33-39, wherein the at least one program pulse parameter for each group includes a first program pulse parameter set for a first program state and a second program pulse parameter set for a second program state; and the access circuitry is to program the memory cell of the first group to the first program state by applying a program pulse in accordance with the first program pulse parameter set and to program the memory cell of the first group to a second program state by applying a program pulse in accordance with the second program pulse parameter set.

Example 41 may include the subject matter of any one of Examples 33-40, wherein the three dimensional crosspoint memory array comprises a plurality of stacked decks, a first subset of groups of the plurality of groups is specific to a first deck of the plurality of stacked decks, and a second subset of groups of the plurality of groups is specific to a second deck of the plurality of stacked decks.

Example 42 may include the subject matter of any one of Examples 33-41, wherein the memory cell comprises a first layer of chalcogenide material to function as a selector device and a second layer of chalcogenide material to function as a storage element.

Example 43 may include the subject matter of any one of Examples 33-42, wherein the memory cell comprises a chalcogenide material to function as both a selector device and a storage element.

Example 44 may include the subject matter of any one of Examples 33-43, wherein a threshold voltage tunability of the first program state of the memory cell is between 50 mV and 1500 mV.

Example 45 may include the subject matter of any one of Examples 33-44, further comprising a plurality of memory chips, wherein a first memory chip of the plurality of memory chips comprises the three dimensional crosspoint memory array and access circuitry.

Example 46 may include the subject matter of Example 45, further comprising a memory controller to communicate with the plurality of memory chips.

Example 47 may include the subject matter of any one of Examples 33-46, wherein the memory device comprises a solid state drive.

Example 48 may include the subject matter of any one of Examples 33-46, wherein the memory device comprises a dual in-line memory module.

Example 49 may include the subject matter of any one of Examples 33-48, further comprising a processor to generate data to be stored by the three dimensional crosspoint memory array, the processor to couple to the at least one memory chip through the storage device controller.

Example 50 may include the subject matter of Example 49, further comprising one or more of: a battery communicatively coupled to the processor, a display communicatively coupled to the processor, or a network interface communicatively coupled to the processor.

What is claimed is:

1. A memory device including:
a three dimensional crosspoint memory array comprising memory cells assigned to a plurality of groups, wherein each group is associated with a respective at least one program pulse parameter based on programming responses of memory cells of that group; and
access circuitry to program a memory cell of a first group of the plurality of groups to a first program state by applying a program pulse having the at least one program pulse parameter associated with the first group.

2. The memory device of claim 1, wherein the at least one program pulse parameter associated with a second group of the plurality of groups is to cause a distribution of threshold voltages of memory cells of the second group programmed to the first program state to align more closely with a distribution of threshold voltages of memory cells of the first group programmed to the first program state than if a default program pulse had been used to program the memory cells of the second group to the first program state.

3. The memory device of claim 1, wherein the memory cells are assigned to the plurality of groups based at least in part on locations of the memory cells within the three dimensional crosspoint memory array.

4. The memory device of claim 1, wherein the at least one program pulse parameter associated with the first group is based at least in part on a number of cycle counts of memory cells of the first group.

5. The memory device of claim 1, wherein the at least one program pulse parameter associated with the first group is based at least in part on an operating temperature associated with the memory device.

6. The memory device of claim 1, wherein the respective at least one program pulse parameter comprises an indication of an amplitude of a program pulse, wherein the indication of the amplitude specifies one or more of a bitline voltage, a wordline voltage, and a programming current.

7. The memory device of claim 1, wherein the respective at least one program pulse parameter comprises an indication of a pulse width of a program pulse.

8. The memory device of claim 1, wherein the respective at least one program pulse parameter comprises at least one program pulse parameter for a first step of the program pulse and at least one program pulse parameter for a second step of the program pulse.

9. The memory device of claim 1, wherein:
at least one program pulse parameter for each group includes a first program pulse parameter set for a first program state and a second program pulse parameter set for a second program state; and
the access circuitry is to program the memory cell of the first group to the first program state by applying a program pulse in accordance with the first program pulse parameter set and to program the memory cell of the first group to a second program state by applying a program pulse in accordance with the second program pulse parameter set.

10. The memory device of claim 1, wherein the three dimensional crosspoint memory array comprises a plurality of stacked decks, a first subset of groups of the plurality of groups is specific to a first deck of the plurality of stacked decks, and a second subset of groups of the plurality of groups is specific to a second deck of the plurality of stacked decks.

11. The memory device of claim 1, wherein the memory cell comprises a first layer of chalcogenide material to function as a selector device and a second layer of chalcogenide material to function as a storage element.

12. The memory device of claim 1, wherein the memory cell comprises a chalcogenide material to function as both a selector device and a storage element.

13. The memory device of claim 1, wherein a threshold voltage tunability of the first program state of the memory cell is between 50 mV and 1500 mV.

14. The memory device of claim 1, further comprising a plurality of memory chips, wherein a first memory chip of the plurality of memory chips comprises the three dimensional crosspoint memory array and access circuitry.

15. The memory device of claim 14, further comprising a memory controller to communicate with the plurality of memory chips.

16. The memory device of claim 1, wherein the memory device comprises a solid state drive.

17. The memory device of claim 1, wherein the memory device comprises a dual in-line memory module.

18. A method comprising:
associating memory cells of a three dimensional crosspoint memory array with a plurality of groups, wherein each group is associated with a respective at least one program pulse parameter based on programming responses of memory cells of that group; and
programming a memory cell of a first group of the plurality of groups to a first program state by applying a program pulse having the at least one program pulse parameter associated with the first group.

19. The method of claim 18, wherein the at least one program pulse parameter associated with a second group of the plurality of groups is to cause a distribution of threshold voltages of memory cells of the second group programmed to the first program state to align more closely with a distribution of threshold voltages of memory cells of the first group programmed to the first program state than if a default program pulse had been used to program the memory cells of the second group to the first program state.

20. A system comprising:
a storage device controller; and
at least one memory chip coupled to the storage device controller, wherein a memory chip comprises:
a three dimensional crosspoint memory array comprising memory cells assigned to a plurality of groups, wherein each group is associated with a respective at least one program pulse parameter based on programming responses of memory cells of that group; and
access circuitry to program a memory cell of a first group of the plurality of groups to a first program state by applying a program pulse having the at least one program pulse parameter associated with the first group.

21. The system of claim 20, further comprising a processor to generate data to be stored by the three dimensional crosspoint memory array, the processor to couple to the at least one memory chip through the storage device controller.

22. The system of claim 21, further comprising one or more of: a battery communicatively coupled to the processor, a display communicatively coupled to the processor, or a network interface communicatively coupled to the processor.
